(19) United States
(12) Patent Application Publication
(10) Pub. No.: US 2023/0266391 A1
(43) Pub. Date: Aug. 24, 2023

(54) DIAGNOSIS APPARATUS, DIAGNOSIS METHOD, AND DIAGNOSIS PROGRAM FOR ROTARY MACHINE

(71) Applicant: MITSUBISHI HEAVY INDUSTRIES, LTD., Tokyo (JP)

(72) Inventors: Koki TATEISHI, Tokyo (JP); Yohei CHISHIKI, Tokyo (JP); Takashi SONODA, Tokyo (JP)

(73) Assignee: MITSUBISHI HEAVY INDUSTRIES, LTD., Tokyo (JP)

(21) Appl. No.: 18/014,047

(22) PCT Filed: Feb. 8, 2021
(86) PCT No.: PCT/JP2021/004522

§ 371 Date: Dec. 30, 2022

(30) Foreign Application Priority Data
Jul. 31, 2020 (JP) 2020-130197

(51) Int. Cl. G01R 31/34

(52) U.S. Cl. CPC G01R 31/343

(57) ABSTRACT

A diagnosis apparatus for a rotary machine includes: an effective value acquisition part configured to acquire, from a current waveform of a current measured during rotation of a rotary machine including a motor or a generator, an effective value of the current; a first index acquisition part configured to acquire a first index indicating a dispersion of a distribution of the effective value; and an abnormality determination part configured to determine whether there is an abnormality in the rotary machine on the basis of comparison of an abnormality index including the first index with a threshold.

### TECHNICAL FIELD

The present disclosure relates to a diagnosis apparatus, a diagnosis method, and a diagnosis program for a rotary machine.

The present application claims priority based on Japanese Patent Application No. 2020-130197 filed Jul. 31, 2020, the entire content of which is incorporated herein by reference.

### BACKGROUND ART

It has been proposed to detect an abnormality in a rotary machine on the basis of a current value measured during rotation of the rotary machine.

For example, Patent Document 1 discloses a diagnosis apparatus for diagnosing a machine including a rotary machine on the basis of current measured during rotation of the rotary machine. In this diagnosis apparatus, an abnormality in the machine is detected by comparing the distribution state of current effective values acquired from the measured current with the distribution state of current effective values acquired from current measured during normal operation of the rotary machine.

### CITATION LIST

### Patent Literature

Patent Document 1: JP6619908B

### SUMMARY

### Problems to be Solved

In the diagnosis apparatus disclosed in Patent Document 1, since the distribution state of current effective values during normal operation of the rotary machine is used for diagnosing, it is necessary to measure the current during normal operation prior to diagnosing the rotary machine. Therefore, the rotary machine cannot be diagnosed at the initial current measurement.

In view of the above, an object of at least one embodiment of the present invention is to provide a diagnosis apparatus, a diagnosis method, and a diagnosis program for a rotary machine whereby it is possible to appropriately diagnose the rotary machine from the initial measurement of current.

### Solution to the Problems

A diagnosis apparatus for a rotary machine according to at least one embodiment of the present invention includes: an effective value acquisition part configured to acquire, from a current waveform of a current measured during rotation of a rotary machine including a motor or a generator, an effective value of the current; a first index acquisition part configured to acquire a first index indicating a dispersion of a distribution of the effective value; and an abnormality determination part configured to determine whether there is an abnormality in the rotary machine on the basis of comparison of an abnormality index including the first index with a threshold.

Further, a diagnosis method for a rotary machine according to at least one embodiment of the present invention includes: a step of acquiring, from a current waveform of a current measured during rotation of a rotary machine including a motor or a generator, an effective value of the current; a step of acquiring a first index indicating a dispersion of a distribution of the effective value; and a step of determining whether there is an abnormality in the rotary machine on the basis of comparison of an abnormality index including the first index with a threshold.

Further, a diagnosis program for a rotary machine according to at least one embodiment of the present invention is configured to cause a compute to execute: a process of acquiring, from a current waveform of a current measured during rotation of a rotary machine including a motor or a generator, an effective value of the current; a process of acquiring a first index indicating a dispersion of a distribution of the effective value; and a process of determining whether there is an abnormality in the rotary machine on the basis of comparison of an abnormality index including the first index with a threshold.

### Advantageous Effects

At least one embodiment of the present invention provides a diagnosis apparatus, a diagnosis method, and a diagnosis program for a rotary machine whereby it is possible to appropriately diagnose the rotary machine from the initial measurement of current.

### BRIEF DESCRIPTION OF DRAWINGS

FIG. 1 is a schematic diagram of a rotary machine to which a diagnosis apparatus is applied according to an embodiment.

FIG. 2 is a schematic diagram of a diagnosis apparatus according to an embodiment.

FIG. 3 is a flowchart of a diagnosis method according to an embodiment.

FIG. 4 is a graph showing an example of current waveform acquired by a diagnosis apparatus according to an embodiment.

FIG. 5 is a graph showing an example of probability distributions of effective values of current during normal operation and abnormal operation of the rotary machine.

FIG. 6 is a graph showing an example of probability distributions of effective values of current during normal operation and abnormal operation of the rotary machine.

FIG. 7 is a graph showing an example of probability distributions of effective values of current during normal operation and abnormal operation of the rotary machine.

FIG. 8 is a graph showing an example of current waveform acquired by a diagnosis apparatus according to an embodiment.

FIG. 9 is a flowchart for describing the process of acquiring divided waveforms in a diagnosis method according to an embodiment.

FIG. 10 is a graph showing an example of current waveform acquired by a diagnosis apparatus according to an embodiment.

FIG. 11 is a graph showing an example of current waveform acquired by a diagnosis apparatus according to an embodiment.

FIG. 12 is a graph showing an example of current waveform acquired by a diagnosis apparatus according to an embodiment.

FIG. 13 is a graph showing an example of current waveform acquired by a diagnosis apparatus according to an embodiment.

### DETAILED DESCRIPTION

Embodiments of the present invention will now be described in detail with reference to the accompanying drawings. It is intended, however, that unless particularly identified, dimensions, materials, shapes, relative positions, and the like of components described in the embodiments shall be interpreted as illustrative only and not intended to limit the scope of the present invention.

### Configuration of Diagnosis Apparatus

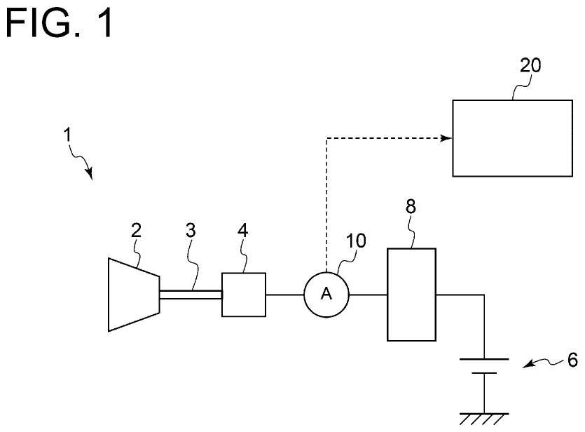

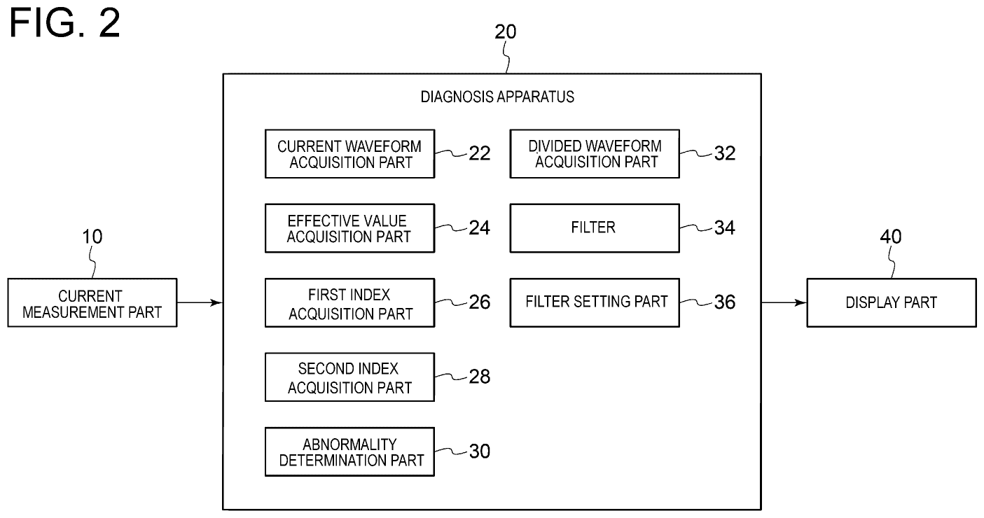

FIG. 1 is a schematic diagram of a rotary machine to which a diagnosis apparatus is applied according to an embodiment. FIG. 2 is a schematic diagram of a diagnosis apparatus according to an embodiment. The diagnosis apparatus according to some embodiments is a diagnosis apparatus for diagnosing a rotary machine including a motor or a generator.

In some embodiments, the rotary machine to be diagnosed includes a motor. A rotary machine 1 shown in FIG. 1 is an example of the rotary machine including a motor, and includes a compressor 2 for compressing a fluid and a motor 4 for driving the compressor 2. The compressor 2 is connected to the motor 4 via an output shaft 3 of the motor 4. The motor 4 is driven by power supply.

The motor 4 may be configured to be driven by AC power. In the exemplary embodiment shown in FIG. 1, DC power from a DC power source 6 (e.g., storage battery) is converted to AC power by an inverter 8 and supplied to the motor 4. In other embodiments, AC power from an AC power supply may be supplied to the motor 4.

In some embodiments, the rotary machine to be diagnosed includes a generator. Such a rotary machine may include, for example, a turbine configured to be driven by a fluid and a generator configured to be driven by the turbine. The generator may be configured to generate AC power.

A diagnosis apparatus 20 is configured to diagnose the rotary machine 1 on the basis of a current measured by a current measurement part 10 during rotation of the rotary machine 1.

The current measurement part 10 is configured to measure a current supplied to the motor (for example, motor 4 in FIG. 1) included in the rotary machine 1 or a current output from the generator included in the rotary machine 1. The current measurement part 10 may be configured to measure a winding current of the motor or the generator included in the rotary machine 1.

The diagnosis apparatus 20 is configured to receive a signal indicating a current measurement value from the current measurement part 10. The diagnosis apparatus 20 may be configured to receive a signal indicating a current measurement value from the current measurement part 10 at a specified sampling period. Further, the diagnosis apparatus 20 is configured to process the signal received from the current measurement part 10 and determine whether there is an abnormality in the rotary machine 1. The diagnosis result by the diagnosis apparatus 20 may be displayed on a display part 40 (e.g., display; see FIG. 2).

An abnormality in the rotary machine 1 to be diagnosed by the diagnosis apparatus 20 is an abnormality in the rotary machine 1 that can affect the current measurement value from the current measurement part 10. Examples of such abnormalities include misalignment (center deviation), cavitation, belt loosening, and ground faults in the rotary machine 1.

As shown in FIG. 2, the diagnosis apparatus 20 according to an embodiment includes a current waveform acquisition part 22, an effective value acquisition part 24, a first index acquisition part 26, a second index acquisition part 28, an abnormality determination part 30, a divided waveform acquisition part 32, a filter 34, and a filter setting part 36.

The diagnosis apparatus 20 includes a calculator equipped with a processor (e.g., CPU), a storage device (memory device; e.g., RAM), an auxiliary storage part, and an interface. The diagnosis apparatus 20 receives a signal indicating a current measurement value from the current measurement part 10 via the interface. The processor is configured to process the signal thus received. In addition, the processor is configured to process programs loaded into the storage device. Thereby, the function of each functional unit (current waveform acquisition part 22, etc.) is implemented.

The processing contents in the diagnosis apparatus 20 may be implemented as programs executed by the processor. The programs may be stored in the auxiliary memory. When executed, these programs are loaded into the storage device. The processor reads out the programs from the storage device to execute instructions included in the programs, respectively.

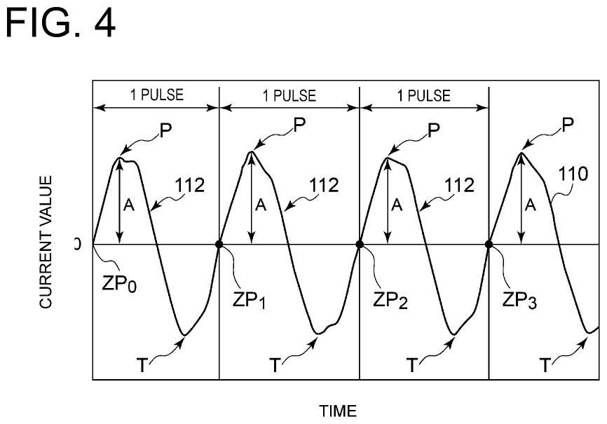

The current waveform acquisition part 22 is configured to acquire a current waveform 110 (see FIG. 4) representing a change in measured current value over time on the basis of the signal received from the current measurement part 10.

The effective value acquisition part 24 is configured to acquire an effective value of the current from the current waveform 110 acquired by the current waveform acquisition part 22. The effective value acquisition part 24 may be configured to acquire an effective value of the current for each of divided waveforms acquired by the divided waveform acquisition part 32, which will be described later.

The first index acquisition part 26 is configured to acquire a first index indicating a dispersion of a distribution of the effective value of the current acquired by the effective value acquisition part 24. The second index acquisition part 28 is configured to acquire a second index indicating a divergence of the effective value of the current acquired by the effective value acquisition part 24 from a theoretical value.

The abnormality determination part 30 is configured to determine whether there is an abnormality in the rotary machine 1 (that is, determine the presence or absence of an abnormality in the rotary machine 1) on the basis of comparison of an abnormality index including the first index and/or the second index with a threshold.

The divided waveform acquisition part 32 is configured to acquire a plurality of divided waveforms 112 by dividing the current waveform 110 acquired by the current waveform acquisition part 22 by a specified number of pulses (see FIG. 4). Here, each divided waveform 112 obtained by dividing the current waveform by a specified number of pulses is a portion of the current waveform 110 that includes a specified number of pairs of peaks and troughs appearing in the current waveform 110 (i.e., waveform for the specified number of cycles approximately). For example, the divided waveform 112 with one pulse is obtained by extracting, from the current waveform 110 acquired by the current waveform acquisition part 22, a portion that includes one pair of a peak and a trough appearing in the current waveform (i.e., waveform for one cycle approximately) (see FIG. 4).

The filter 34 is a filter for reducing noise components (high frequency components) from the signal received from the current measurement part 10. The filter setting part 36 is configured to be able to change settings such as the time constant of the filter 34.

### Diagnosis Flow of Rotary Machine

Hereinafter, the diagnosis flow for a rotary machine according to an embodiment will be described more specifically. The following describes the case where the above-described diagnosis apparatus 20 is used to execute a diagnosis method for a rotary machine according to an embodiment, but in some embodiments, another apparatus may be used to execute the diagnosis method for a rotary machine.

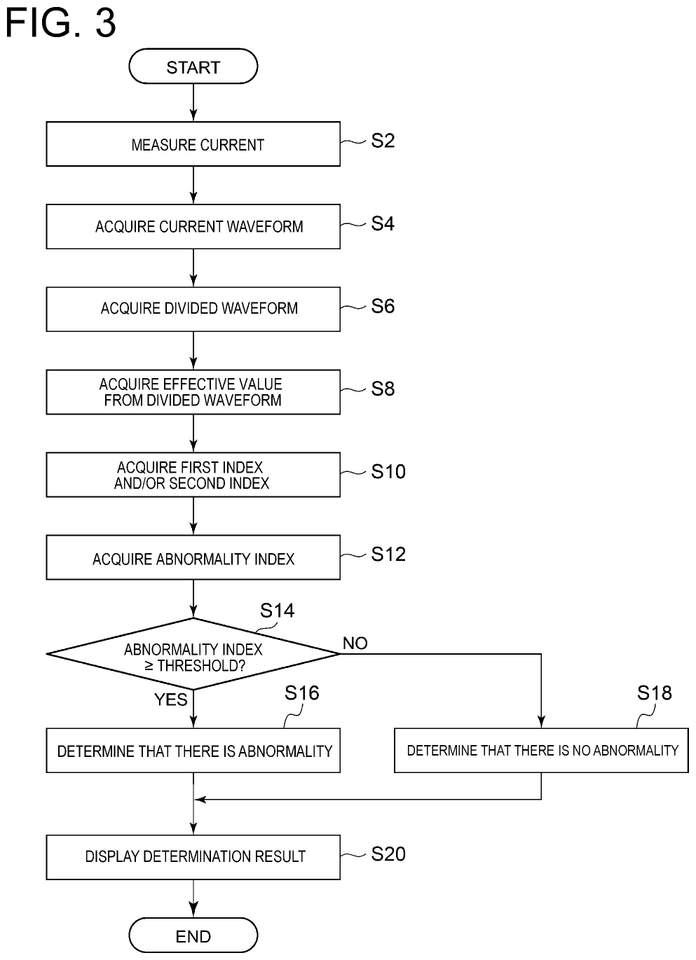

FIG. 3 is a flowchart of the diagnosis method according to an embodiment. As shown in FIG. 3, in an embodiment, first, using the current measurement part 10, a current is measured during rotation of the rotary machine 1 (S2). The current measured in step S2 may be a current supplied to the motor or a current output from the generator.

Then, a current waveform 110 representing a change in measured current value over time is acquired by the current waveform acquisition part 22 on the basis of a signal received from the current measurement part 10 (signal indicating a current measurement value) (S4). Here, FIG. 4 is a graph showing an example of the current waveform 110 acquired by the current waveform acquisition part 22 (diagnosis apparatus 20) according to an embodiment. As shown in FIG. 4, the current waveform 110 acquired in step S4 is an AC waveform in which peaks P (positive peaks) and troughs T (negative peaks) appear alternately.

Then, the current waveform 110 acquired in step S4 is divided by a specified number of pulses to acquire a plurality of divided waveforms 112 by the divided waveform acquisition part 32 (S6). In step S6, the plurality of divided waveforms 112 (divided waveforms with one pulse; see FIG. 4) may be acquired by dividing the current waveform 110 by one pulse. In step S6, the plurality divided waveform 112 may be acquired by dividing the current waveform 110 at each period related to the rotation speed of the rotary machine 1 or at each period related to the cycle of the alternating current to extract portions included in each period from the current waveform 110. Alternatively, as will be described later, the plurality of divided waveforms 112 may be acquired by dividing the current waveform 110 on the basis of zero-crossing points grasped from the current waveform 110.

The following describes the case where, in step S6, the current waveform 110 is divided by one pulse to acquire the plurality of divided waveforms 112. However, the following description can also be applied to the case where the current waveform 110 is divided by every two or more pulses to acquire divided waveforms.

Then, for each of the divided waveforms 112 obtained in step S6, an effective value of the current is acquired by the effective value acquisition part 24 (S8). Here, the effective value Iᵣₘₛ of the current of each divided waveform 112 can be calculated as the square root of the mean (time mean) of the squares of current measurement values I of each divided waveform 112. If the current measurement value is obtained at a specified sampling period, the effective value Iᵣₘₛ of the current of the divided waveform 112 can be expressed by the following equation (A), using the current values Iₜ at multiple measurement points in each divided waveform 112 and the time length T from the start point to the end point of each divided waveform 112.

$$\begin{matrix}( Expression 1 ) & \\ {I}_{r n s} = \sqrt{\frac{1}{T} {{\sum }_{t}}^{T} {I}_{t}^{2}} & ( A )\end{matrix}$$

In step S8, for each of the divided waveforms 112, the current value of the divided waveform 112 may be divided by the amplitude A of the divided waveform 112 to obtain the normalized divided waveform (divided waveform with a peak value (amplitude) of 1), and the effective value Iᵣₘₛ may be calculated for the normalized divided waveform.

Then, a first index J₁ indicating a dispersion of the distribution of the plurality of effective values Iᵣₘₛ (i.e., effective value Iᵣₘₛ for each of the plurality of divided waveforms 112) obtained in step S8 is acquired by the first index acquisition part 26 (S10).

Then, the abnormality determination part 30 acquires an abnormality index J_{AB} on the basis of the first index J₁ acquired in step S10. The abnormality index J_{AB} is an index that indicates the degree of abnormality of the rotary machine 1. Then, the abnormality determination part 30 compares the abnormality index J_{AB} with a threshold (S14). If the abnormality index J_{AB} is not less than the threshold, it is determined that there is an abnormality in the rotary machine 1 (S16). Conversely, if the abnormality index J_{AB} is less than the threshold, it is determined that there is no abnormality in the rotary machine 1 (S18). The determination results in steps S16 and S18 may be displayed on the display part 40 (S20).

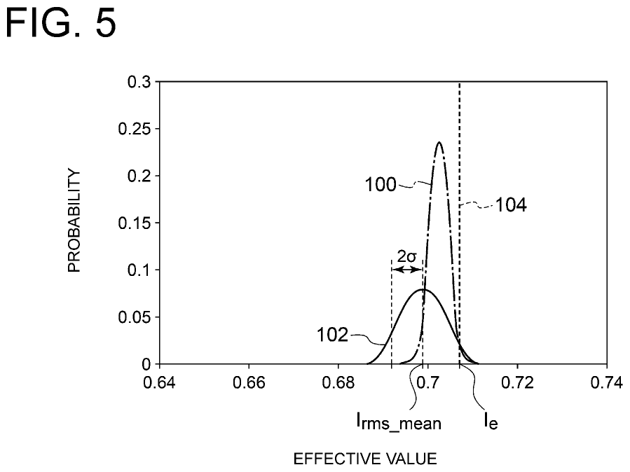

FIGS. 5 to 7 are each a graph showing an example of probability distributions of the effective values of the current during normal operation and abnormal operation of the rotary machine 1. The probability distribution is acquired on the basis of the effective value of each of the plurality of divided waveforms obtained by dividing the current waveform. In the graphs of FIGS. 5 to 7, the horizontal axis represents the effective value and the vertical axis represents the probability. In FIGS. 5 to 7, the curve 100 indicates the probability distribution of the current effective value when the rotary machine 1 is normal (when no abnormality has occurred), while the curve 102 indicates the probability distribution of the current effective value when an abnormality has occurred in the rotary machine 1. The dashed line 104 indicates the theoretical value of the effective value of the current (effective value of sine wave) Iₑ.

According to findings of the present inventors, when an abnormality occurs in the rotary machine 1 including the motor (for example, motor 4 in FIG. 1) or the generator, disturbance occurs in the measured current waveform 110, which may increase the dispersion of the distribution of the effective value obtained from the current waveform 110. For example, in the cases shown in FIGS. 5 to 7, the curve 102 of the probability distribution of the current effective value when the rotary machine 1 is abnormal is wider in the horizontal direction than the curve 100 of the probability distribution of the current effective value when the rotary machine 1 is normal. In other words, the dispersion of the distribution of the effective value obtained from the current waveform is larger when an abnormality has occurred in the rotary machine 1 than when it is normal.

In this regard, according to the above-described embodiment, it is possible to determine whether there is an abnormality in the rotary machine 1 by comparing the abnormality index J_{AB} that includes the first index J₁ indicating the dispersion of the distribution of the effective value of the measured current with the threshold. Therefore, in diagnosing the rotary machine 1, it is not necessary to measure the current during normal operation of the rotary machine 1 in advance. Thus, it is possible to appropriately diagnose the rotary machine 1 from the initial measurement of current.

In an embodiment, in the above-described step S12, the abnormality determination part 30 acquires the abnormality index J_{AB} that includes the first index J₁ indicating the dispersion of the distribution of the plurality of effective values Iᵣₘₛ (e.g., standard deviation σ of the plurality of effective values Iᵣₘₛ). The abnormality index J_{AB} may be, for example, a standard deviation σ of the plurality of effective values Iᵣₘₛ, or an integer multiple of the standard deviation σ (for example, 2σ, 3σ, etc.).

In this case, the threshold to be compared with the abnormality index J_{AB} in step S14 may be decided based on amplitude A of the plurality of divided waveforms 112. The threshold may be decided based on the mean Aₘₑₐₙ of amplitude A of the plurality of divided waveforms 112, or the amplitude A₀ (=1) of the above-described normalized divided waveform. For example, it may be a value k times the mean Aₘₑₐₙ of amplitude A or the amplitude A₀ (where k>0).

More specifically, for example, the abnormality index J_{AB} may be 2σ (twice the standard deviation σ) of the current effective value, and the threshold may be 0.03×A (or 0.03×Aₘₑₐₙ, or 0.03×A₀), and in step S14, it may be determined whether there is an abnormality in the rotary machine 1 according to whether the abnormality index J_{AB} is not less than the threshold.

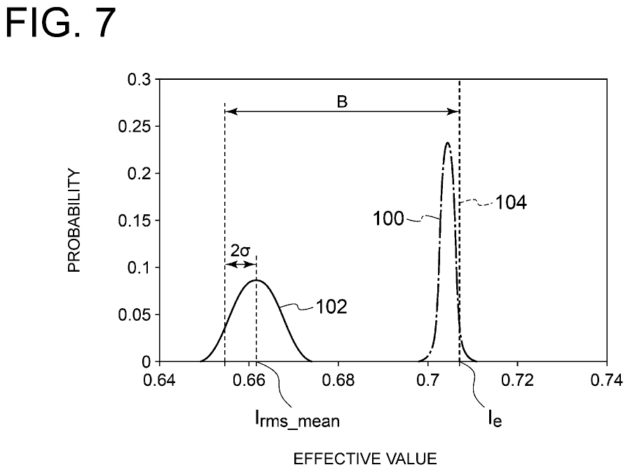

As described above, when an abnormality occurs in the rotary machine 1, disturbance occurs in the measured current waveform 110, which may increase the dispersion of the distribution of the effective value obtained from the current waveform 110. In this case, the standard deviation σ of the current effective value when the rotary machine 1 is abnormal is larger than the standard deviation σ of the current effective value when the rotary machine 1 is normal (see FIGS. 5 and 7). FIGS. 5 to 7 show twice (2σ) the standard deviation σ of the current effective value when the rotary machine 1 is abnormal.

In this regard, according to the above-described embodiment, an abnormality in the rotary machine 1 can be detected simply and appropriately on the basis of comparison between the standard deviation σ of the current effective value or its integer multiple and the threshold.

Further, when using the threshold decided based on the amplitude of the current waveform in step S14, an abnormality in the rotary machine can be detected simply and appropriately on the basis of this threshold.

In an embodiment, in step S10, in addition to acquiring the first index J₁ by the first index acquisition part 26, a second index J₂ may be acquired by the second index acquisition part 28. The second index J₂ is an index indicating a divergence of an average value of the plurality of effective values Iᵣₘₛ obtained in step S8 from a theoretical value Iₑ of the effective value of the divided waveform 112. Here, if the normalization process is performed, the theoretical value Iₑ of the effective value of the divided waveform 112 is the effective value of a sine wave with amplitude A₀ (=1) of the normalized divided waveform. The second index J₂ may be a difference (I_{rms_mean}−Iₑ) between the average value I_{rms_mean} of the plurality of effective values Iᵣₘₛ and the theoretical value Iₑ of the effective value of the divided waveform 112 or may be the absolute value (|I_{rms_mean}−Iₑ|) thereof.

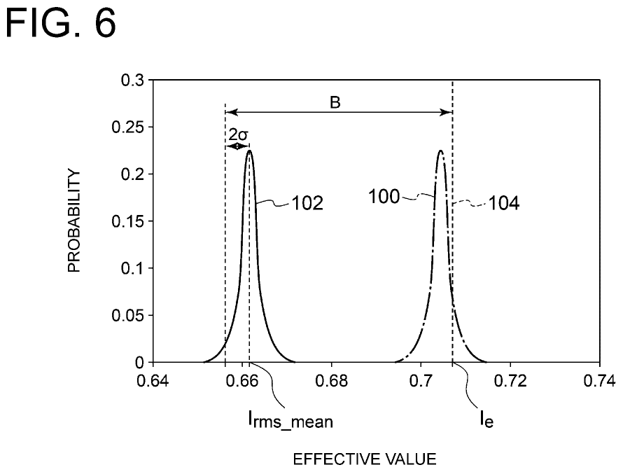

In step S12, the abnormality index J_{AB} that includes the first index J₁ and the second index J₂ may be acquired. The abnormality index J_{AB} may be, for example, the linear sum of the first index J₁ and the second index J₂ (a×J₁+b×J₂, provided that a>0 and b>0). More specifically, the abnormality index J_{AB} may be the sum B (see FIGS. 6 and 7) of the absolute value (|I_{rms_mean}−Iₑ|) of the difference from the theoretical value Iₑ of the effective value of the divided waveform 112 and 2σ (twice the standard deviation σ) of the current effective value. Then, in steps S14 to S18, it may be determined whether there is an abnormality in the rotary machine 1 on the basis of comparison between the abnormality index J_{AB} thus acquired and the threshold.

According to findings of the present inventors, when an abnormality occurs in the rotary machine 1 including the motor (for example, motor 4 in FIG. 1) or the generator, the average value of the effective value obtained from the measured current waveform may change. For example, in the cases shown in FIGS. 6 and 7, the average value I_{rms_mean} of the current effective value when the rotary machine 1 is abnormal (see the curve 102) is smaller than the average value of the current effective value when the rotary machine 1 is normal (see the curve 100).

Here, especially in the case shown in FIG. 6, the curves indicating the probability distribution of the effective value have substantially the same shape when the rotary machine 1 is normal (see the curve 100) and when the rotary machine 1 is abnormal (see the curve 102), and there is not much change in the dispersion (standard deviation σ, etc.) of the distribution of the effective value obtained from the current waveform 110. Therefore, when using the abnormality index J_{AB} based only on the first index J₁ indicating the dispersion of the distribution of the effective value, it may not be possible to appropriately determine whether there is an abnormality in the rotary machine 1.

In this regard, in the above-described embodiment, in addition to the first index J₁, the second index J₂ indicating the divergence of the average value of the effective value obtained from the current waveform from the theoretical value is used to determine whether there is an abnormality in the rotary machine 1. Therefore, as in the case shown in FIG. 6, for example, even if the dispersion of the effective value distribution does not increase when an abnormality occurs in the rotary machine 1, an abnormality in the rotary machine 1 can be detected. Thus, it is possible to detect an abnormality in the rotary machine 1 more reliably.

In some embodiments, in step S6, the divided waveform acquisition part 32 may acquire a plurality of divided waveforms 112 by dividing the current waveform 110 acquired in step S4 at a plurality of zero-crossing points ZP (e.g., ZP₀ to ZP₃ in FIG. 4). Here, the zero-crossing point is a point of the current waveform where the current passes through zero and the sign of the current changes in the same direction (from negative to positive, or from positive to negative). The zero-crossing points ZP₀ to ZP₃ in FIG. 4 are points where the current passes through zero and the sign of the current changes from negative to positive.

In the case of the current waveform 110 shown in FIG. 4, for example, portions between pairs of adjacent zero-crossing points (e.g., between ZP₀ and ZP₁, between ZP₁ and ZP₂, etc.) can be obtained as the divided waveforms 112.

When dividing the current waveform 110, it is conceivable to divide the current waveform by a specified frequency (such as frequency associated with the rotation speed of the rotary machine), but in this case, the number of samples per period may not be stable, depending on the sampling interval of the measurement device or the like. In this regard, according to the above-described embodiment, the current waveform 110 is divided at the zero-crossing points. Thus, it is possible to obtain a plurality of divided waveforms 112 whose current values are zero at the start point (zero-crossing point) and the end point (i.e., zero-crossing point). Therefore, for each of the plurality of divided waveforms 112 thus obtained, it is possible to acquire the effective value appropriately in step S8.

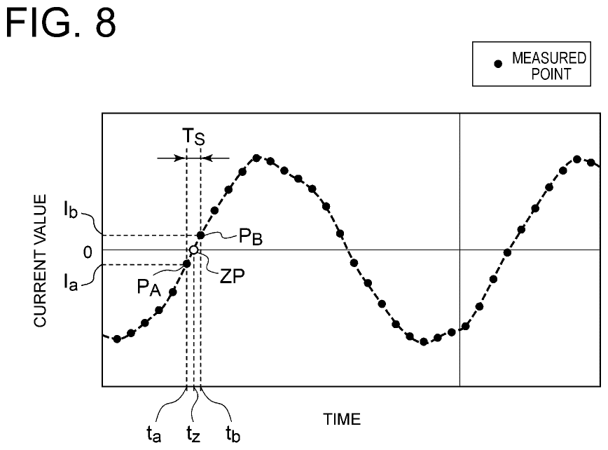

FIG. 8 is a chart showing an example of the current waveform 110 acquired in step S4. In an embodiment, the current waveform 110 obtained in step S4, as shown in FIG. 8, is represented as a curve connecting current measurement values acquired at a specified sampling period Ts. In an embodiment, in step S6, the divided waveform acquisition part 32 may identify the zero-crossing points ZP by linear interpolation of two measurement values with different signs (e.g., measurement values at measurement points P_{A} and P_{B} in FIG. 8).

In the example shown in FIG. 8, the current value passes through zero during a period between the measurement time tₐ at the measurement point P_{A}, where the sign of the measured current is positive, and the measurement time t_{b} at the measurement point P_{B}, where the sign of the measured current is negative, but there is no measurement point with zero current value in this period. In this case, the time t_{z} of the zero-crossing point ZP between the measurement points P_{A} and P_{B} can be identified by linear interpolation based on the time tₐ and measured current value Iₐ of the measurement point P_{A} and the time t_{b} and measured current value I_{b} of the measurement point P_{B}.

As described above, current measurement values may be acquired as discrete measurement values at each predetermined sampling period. In this regard, in the above-described embodiment, the zero-crossing points ZP can be identified by linear interpolation of two measurement values with different signs (e.g., P_{A} and P_{B}) among the plurality of current measurement values acquired at the specified sampling period Ts. Thus, even if the plurality of discrete current measurement values does not include a measurement point with zero current value, the current waveform 110 can be divided into the divided waveforms 112 appropriately.

In some embodiments, in step S4, the current waveform acquisition part 22 may reduce noise components (high frequency components) from the signal received from the current measurement part 10 (signal indicating a current measurement value) with a filter 34 to acquire the current waveform 110. In an embodiment, in step S6, the divided waveform acquisition part 32 may identify the zero-crossing points ZP from the current waveform 110 obtained on the basis of the signal processed by the filter 34.

In a current waveform obtained from a signal containing noise, points with zero current value may randomly appear in addition to the inherent (i.e., noise-free) zero-crossing points ZP due to waveform disturbance caused by noise. In this regard, in the above-described embodiment, since the zero-crossing points ZP are identified on the basis of the signal from which noise components have been reduced by the filter 34, the divided waveforms 112 can be obtained by dividing the current waveform 110 more appropriately on the basis of the zero-crossing points ZP thus identified.

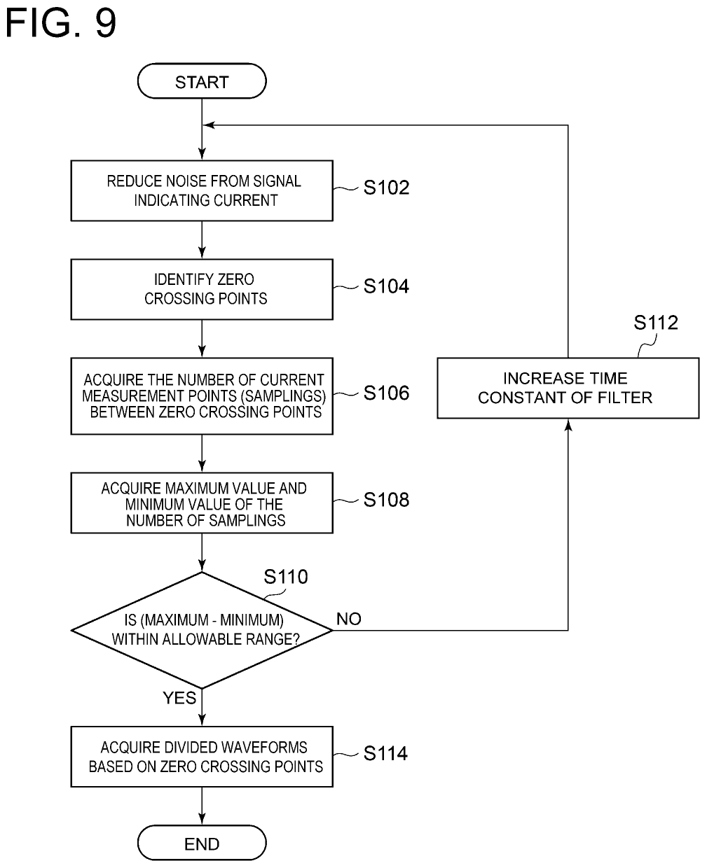

FIG. 9 is a flowchart for describing the process of acquiring divided waveforms in the diagnosis method and the diagnosis apparatus according to an embodiment.

As shown in FIG. 9, in an embodiment, with the filter 34, noise is reduced from the signal indicating the current measurement value measured in step S2 to obtain a current waveform 110 (S102, S4 in FIG. 3). Then, a plurality of zero-crossing points ZP are identified from the obtained current waveform 110 (S104). In step S104, as described above, the linear interpolation method may be used.

Then, the number of current measurement points (number of samples) included between each zero-crossing point of the plurality of zero-crossing points ZP is acquired (S106). Further, the maximum and minimum values of the number of current measurement points included between each zero-crossing point are acquired (S108).

Then, it is determined whether the difference between the maximum and minimum values obtained in step S108 is within an allowable range (S110). If the difference is outside the allowable range (No in S110), the filter setting part 36 increases the time constant of the filter 34 (S112) and returns to step S102. Then, steps S102 to S108 are repeated using the filter 34 with the new time constant set.

On the other hand, if the difference is within the allowable range in step S110 (Yes in S110), a plurality of divided waveforms are obtained on the basis of the current waveform 110 and the zero-crossing points ZP obtained in the last steps S102 and S104 (S114, S6 in FIG. 3).

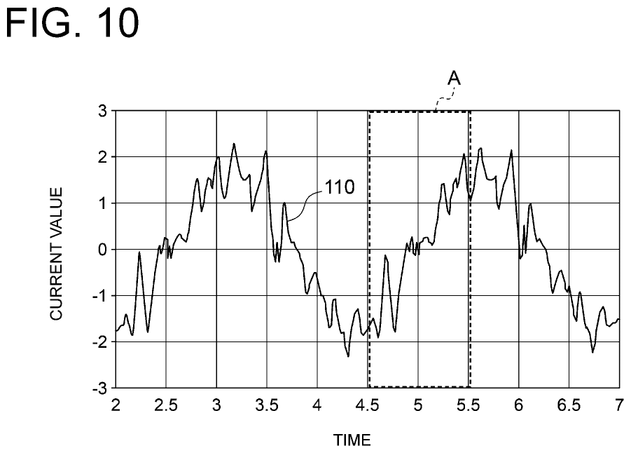

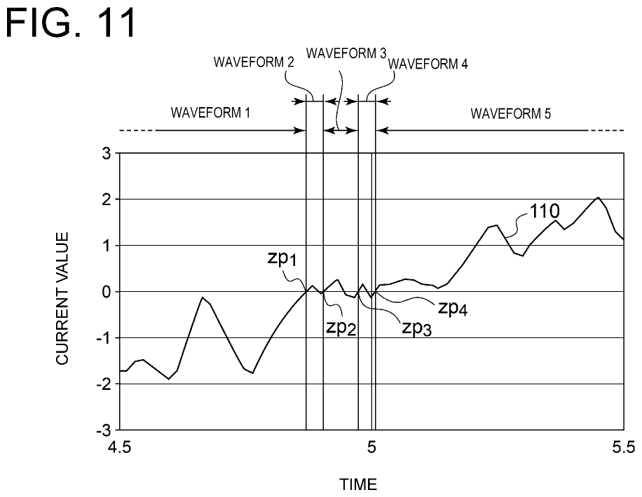

Here, FIGS. 10 and 11 are graphs showing an example of the current waveform 110 when the difference between the maximum and minimum values obtained in step S108 is outside the allowable range (No in step S108). FIG. 11 is an enlarged view of the portion A shown in FIG. 10.

The current waveform shown in FIGS. 10 and 11 contains a large amount of noise, and due to waveform disturbance caused by noise, many points with zero current value randomly appear in addition to the inherent zero-crossing points (zero-crossing points that would appear at a period corresponding to the rotation speed of the rotary machine 1). For example, as shown in FIG. 11, zero-crossing points zp1 to zp4 are contained in a relatively narrow time range (range of 4.5 to 5.5 on the horizontal axis in the graph). The period of this portion A (see FIG. 10) originally includes only one point (zero-crossing point) where the current value changes from negative to positive (based on the rotation speed of the rotary machine 1). If the current waveform is divided based on these zero-crossing points zp1 to zp4, many waveforms with random period (e.g., waveforms 1 to 5 shown in FIG. 11) are obtained as divided waveforms, and appropriate divided waveforms cannot be obtained.

In this case, there is a large variation in the time length between zero-crossing points (time length of waveforms 1 to 5 in FIG. 11). Therefore, variation in the number of current measurement points (number of samples) included between each zero-crossing point is also large, and the difference between the maximum and minimum values of the number of samples is large. Therefore, by changing the time constant of the filter 34 so that the difference between the maximum and minimum values of the number of current measurement points (number of samples) included between each zero-crossing point falls within an allowable range (steps S110 to S112), it is possible to reduce variation in the number of current measurement points (number of samples) included between each zero-crossing point.

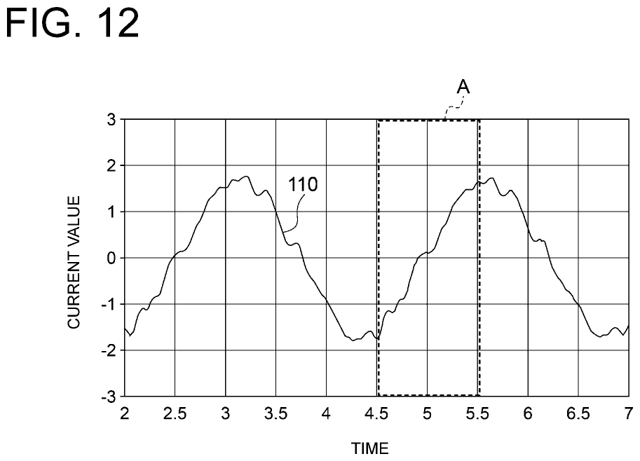

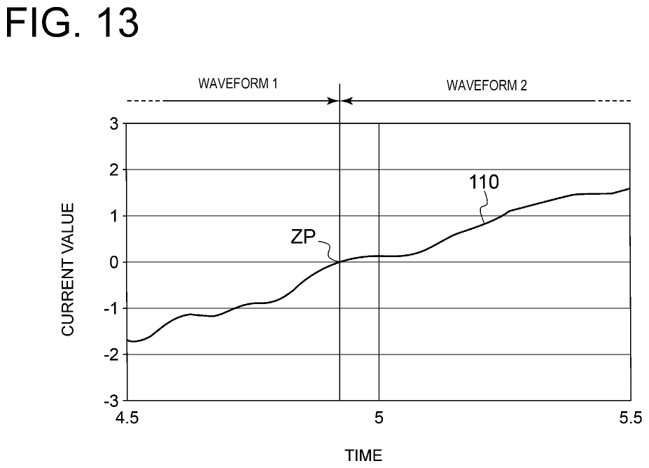

Here, FIGS. 12 and 13 are graphs showing an example of the current waveform 110 when the difference between the maximum and minimum values obtained in step S108 is within the allowable range. FIG. 13 is an enlarged view of the portion A shown in FIG. 12. As can be seen by comparing FIGS. 10 and 12 or FIGS. 11 and 13, noise in the current waveform 110 is reduced in FIGS. 12 and 13 compared to FIGS. 10 and 11, and the portion A contains only one zero-crossing point ZR This indicates that increasing the time constant of the filter 34 appropriately makes it possible to extract from the current waveform 110 only the inherent zero-crossing points ZP (zero-crossing points that would appear at a period corresponding to the rotation speed of the rotary machine 1). By dividing the current waveform on the basis of the plurality of zero-crossing points ZP appropriately extracted, the divided waveforms can be obtained appropriately.

As described above, when the signal contains noise, points with zero current value appear randomly in addition to the inherent zero-crossing points ZR For this reason, the divided waveforms obtained on the basis of such apparent zero-crossing points zp may have large variations in the length from the start point to the end point (period of divided waveform) and the number of samples.

In this regard, according to the above-described embodiment, the filter setting part 36 increases the time constant of the filter 34 until the difference between the maximum and minimum values of the number of sampling measurement values of the current included in each of the divided waveforms (or between a pair of zero-crossing points in the current waveform 110) falls within the allowable range. Thus, it is possible to reduce variation in the number of sampling current measurement values included in the divided waveforms 112 obtained on the basis of the zero-crossing points ZP from the signal processed by the filter 34. Thus, it is possible to obtain the divided waveforms by dividing the current waveform 110 more appropriately.

In an embodiment, the filter setting part 36 may be configured to repeatedly increase the time constant by a predetermined amount until the difference in the number of sampling measurement values of the current included in each of the divided waveforms (or between a pair of zero-crossing points in the current waveform 110) falls within the allowable range. That is, in an embodiment, in step S112, the time constant of the filter 34 may be increased by a predetermined amount. In this case, the time constant of the filter 34 increases in proportion to the number of loops in steps S102 to S110.

According to the above-described embodiment, since the time constant is repeatedly increased by the predetermined amount until the difference between maximum and minimum values of the number of sampling measurement values of the current included in the divided waveforms (or between a pair of zero-crossing points in the current waveform) falls within the allowable range, it is possible to reliably reduce variation in the number of sampling current measurement values included in the divided waveforms 112 obtained on the basis of the zero-crossing points ZP from the signal processed by the filter 34. Thus, it is possible to obtain the divided waveforms 112 by dividing the current waveform 110 more appropriately.

The contents described in the above embodiments would be understood as follows, for instance.

(1) A diagnosis apparatus (20) for a rotary machine (1) according to at least one embodiment of the present invention includes: an effective value acquisition part (22) configured to acquire, from a current waveform (110) of a current measured during rotation of a rotary machine including a motor (4) or a generator, an effective value of the current; a first index acquisition part (26) configured to acquire a first index (J₁) indicating a dispersion of a distribution of the effective value; and an abnormality determination part (30) configured to determine whether there is an abnormality in the rotary machine on the basis of comparison of an abnormality index (J_{AB}) including the first index with a threshold.

According to findings of the present inventors, when an abnormality occurs in the rotary machine including the motor or the generator, disturbance occurs in the measured current waveform, which may increase the dispersion of the distribution of the effective value obtained from the current waveform. In this regard, with the above configuration (1), it is possible to determine whether there is an abnormality in the rotary machine by comparing the abnormality index that includes the first index indicating a dispersion of the distribution of the effective value of the measured current with the threshold. Therefore, in diagnosing the rotary machine, it is not necessary to measure the current during normal operation of the rotary machine in advance. Thus, it is possible to appropriately diagnose the rotary machine from the initial measurement of current.

(2) In some embodiments, in the above configuration (1), the threshold is a threshold decided based on an amplitude of the current waveform.

With the above configuration (2), since the threshold decided based on the amplitude of the current waveform is used, an abnormality in the rotary machine can be detected simply and appropriately on the basis of this threshold.

(3) In some embodiments, in the above configuration (1) or (2), the first index acquisition part is configured to acquire a standard deviation of the effective value as the first index. The abnormality determination part is configured to determine that the rotary machine is abnormal when the first index as the abnormality index is not less than the threshold.

With the above configuration (3), an abnormality in the rotary machine can be detected simply and appropriately on the basis of comparison between the standard deviation of the current effective value and the threshold.

(4) In some embodiments, in the above configuration (1) or (2), the diagnosis apparatus for a rotary machine includes a second index acquisition part (28) configured to acquire a second index (J₂) indicating a divergence of an average value of the effective value from a theoretical value. The abnormality determination part is configured to determine whether there is an abnormality in the rotary machine on the basis of comparison of the abnormality index including the first index and the second index with the threshold.

According to findings of the present inventors, when an abnormality occurs in the rotary machine including the motor or the generator, the average value of the effective value obtained from the measured current waveform may change. In this regard, with the above configuration (4), in addition to the first index, the second index indicating the divergence of the average value of the effective value obtained from the current waveform from the theoretical value is used to determine whether there is an abnormality in the rotary machine. Therefore, even if the dispersion of the effective value distribution does not increase when an abnormality occurs in the rotary machine, an abnormality in the rotary machine can be detected. Thus, it is possible to detect an abnormality in the rotary machine more reliably.

(5) In some embodiments, in any one of the above configurations (1) to (4), the diagnosis apparatus for a rotary machine includes a divided waveform acquisition part (32) configured to acquire a divided waveform with a specified number of pulses from the current waveform. The effective value acquisition part is configured to acquire the effective value of the current for each divided waveform.

With the above configuration (5), since the divided waveform with a specified number of pulses is acquired from the current waveform obtained by current measurement, by acquiring the effective value for each divided waveform thus obtained, it is possible to acquire the first index indicating the dispersion of the distribution of the effective value appropriately. Thus, it is possible to determine whether there is an abnormality in the rotary machine appropriately using the first index thus acquired.

(6) In some embodiments, in the above configuration (5), the divided waveform acquisition part is configured to acquire a plurality of the divided waveforms by dividing the current waveform at a plurality of zero-crossing points (ZP) of the current waveform where the current passes through zero and a sign of the current changes in the same direction.

When dividing the current waveform, it is conceivable to divide the current waveform by a specified frequency (such as frequency associated with the rotation speed of the rotary machine), but in this case, the number of samples per period may not be stable, depending on the sampling interval of the measurement device or the like.

In this regard, with the above configuration (6), the current waveform is divided at the zero-crossing points of the current waveform where the current passes through zero and the sign of the current changes in the same direction (from negative to positive, or from positive to negative). As a result, it is possible to obtain a plurality of divided waveforms whose current values are zero at the start point and the end point, and for each of the plurality of divided waveforms thus obtained, it is possible to acquire the effective value appropriately.

(7) In some embodiments, in the above configuration (6), the current waveform is represented as a curve connecting measurement values of the current acquired at a specified sampling period. The divided waveform acquisition part is configured to identify the zero-crossing points by linear interpolation of two of the measurement values with different signs.

Current measurement values may be acquired as discrete measurement values at each predetermined sampling period. With the above configuration (7), since the zero-crossing points are identified by linear interpolation of two measurement values with different signs among the plurality of current measurement values acquired at a specified sampling period, even if the plurality of discrete current measurement values does not include a measurement point with zero current value, the current waveform can be divided into the divided waveforms appropriately.

(8) In some embodiments, in the above configuration (7), the diagnosis apparatus for a rotary machine includes a filter (34) configured to reduce noise components from a signal indicating the current. The divided waveform acquisition part is configured to identify the zero-crossing points on the basis of the signal processed by the filter.

In a signal containing noise, points with zero current value may randomly appear in addition to the inherent (i.e., noise-free) zero-crossing points due to waveform disturbance caused by noise. In this regard, with the above configuration (8), since the zero-crossing points are identified on the basis of the signal from which noise components have been reduced by the filter, the divided waveforms can be obtained by dividing the current waveform more appropriately on the basis of the zero-crossing points thus identified.

(9) In some embodiments, in the above configuration (8), the diagnosis apparatus for a rotary machine includes a filter setting part (36) configured to increase a time constant of the filter so that a difference between a maximum value and a minimum value of the number of sampling measurement values of the current included in each of the plurality of divided waveforms falls within an allowable range.

As described above, when the signal contains noise, points with zero current value appear randomly in addition to the inherent zero-crossing points. For this reason, the divided waveforms obtained on the basis of such apparent zero-crossing points may have large variations in the length from the start point to the end point (period of divided waveform) and the number of samples. In this regard, with the above configuration (9), since the time constant is increased so that the difference between maximum and minimum values of the number of sampling measurement values of the current included in the plurality of divided waveforms falls within the allowable range, it is possible to reduce variation in the number of sampling current measurement values included in the divided waveforms obtained on the basis of the zero-crossing points from the signal processed by the filter. Thus, it is possible to obtain the divided waveforms by dividing the current waveform more appropriately.

(10) In some embodiments, in the above configuration (9), the filter setting part is configured to repeatedly increase the time constant by a predetermined amount until the difference falls within the allowable range.

With the above configuration (10), since the time constant is repeatedly increased by the predetermined amount until the difference between maximum and minimum values of the number of sampling measurement values of the current included in the divided waveforms falls within the allowable range, it is possible to reliably reduce variation in the number of sampling current measurement values included in the divided waveforms obtained on the basis of the zero-crossing points from the signal processed by the filter. Thus, it is possible to obtain the divided waveforms by dividing the current waveform more appropriately.

(11) A diagnosis method for a rotary machine according to an embodiment of the present invention includes: a step (S8) of acquiring, from a current waveform of a current measured during rotation of a rotary machine including a motor or a generator, an effective value of the current; a step (S10) of acquiring a first index indicating a dispersion of a distribution of the effective value; and a step (S14 to S18) of determining whether there is an abnormality in the rotary machine on the basis of comparison of an abnormality index including the first index with a threshold.

With the above method (11), it is possible to determine whether there is an abnormality in the rotary machine by comparing the abnormality index that includes the first index indicating the dispersion of the distribution of the effective value of the measured current with the threshold. Therefore, in diagnosing the rotary machine, it is not necessary to measure the current during normal operation of the rotary machine in advance. Thus, it is possible to appropriately diagnose the rotary machine from the initial measurement of current.

(12) A diagnosis program for a rotary machine according to an embodiment of the present invention is configured to cause a compute to execute: a process of acquiring, from a current waveform of a current measured during rotation of a rotary machine including a motor or a generator, an effective value of the current; a process of acquiring a first index indicating a dispersion of a distribution of the effective value; and a process of determining whether there is an abnormality in the rotary machine on the basis of comparison of an abnormality index including the first index with a threshold.

With the above program (12), it is possible to determine whether there is an abnormality in the rotary machine by comparing the abnormality index that includes the first index indicating the dispersion of the distribution of the effective value of the measured current with the threshold. Therefore, in diagnosing the rotary machine, it is not necessary to measure the current during normal operation of the rotary machine in advance. Thus, it is possible to appropriately diagnose the rotary machine from the initial measurement of current.

Embodiments of the present invention were described in detail above, but the present invention is not limited thereto, and various amendments and modifications may be implemented.

Further, in the present specification, an expression of relative or absolute arrangement such as “in a direction”, “along a direction”, “parallel”, “orthogonal”, “centered”, “concentric” and “coaxial” shall not be construed as indicating only the arrangement in a strict literal sense, but also includes a state where the arrangement is relatively displaced by a tolerance, or by an angle or a distance whereby it is possible to achieve the same function.

For instance, an expression of an equal state such as “same” “equal” and “uniform” shall not be construed as indicating only the state in which the feature is strictly equal, but also includes a state in which there is a tolerance or a difference that can still achieve the same function.

Further, an expression of a shape such as a rectangular shape or a cylindrical shape shall not be construed as only the geometrically strict shape, but also includes a shape with unevenness or chamfered corners within the range in which the same effect can be achieved.

On the other hand, an expression such as “comprise”, “include”, and “have” are not intended to be exclusive of other components.

### REFERENCE SIGNS LIST

1 Rotary machine

2 Compressor

3 Output shaft

4 Motor

5 Waveform

6 DC power source

8 Inverter

10 Current measurement part

20 Diagnosis apparatus

22 Current waveform acquisition part

24 Effective value acquisition part

26 First index acquisition part

28 Second index acquisition part

30 Abnormality determination part

32 Divided waveform acquisition part

34 Filter

36 Filter setting part

40 Display part

100 Probability distribution of effective value during normal operation

102 Probability distribution of effective value during abnormal operation

104 Theoretical value of effective value

110 Current waveform

112 Divided waveform

P Peak

T Trough

ZP Zero-crossing point

1. 42. (canceled)

13. A diagnosis apparatus for a rotary machine, comprising:
an effective value acquisition part configured to acquire, from a current waveform of a current measured during rotation of a rotary machine including a motor or a generator, an effective value of the current;
a first index acquisition part configured to acquire a first index indicating a dispersion of a distribution of the effective value;
an abnormality determination part configured to determine whether there is an abnormality in the rotary machine on the basis of comparison of an abnormality index including the first index with a threshold; and
a second index acquisition part configured to acquire a second index indicating a divergence of an average value of the effective value from a theoretical value,
wherein the abnormality determination part is configured to determine whether there is an abnormality in the rotary machine on the basis of comparison of the abnormality index including the first index and the second index with the threshold.

14. The diagnosis apparatus for a rotary machine according to claim 13,
wherein the threshold is a threshold decided based on an amplitude of the current waveform.

15. The diagnosis apparatus for a rotary machine according to claim 13,
wherein the first index acquisition part is configured to acquire a standard deviation of the effective value as the first index, and
wherein the abnormality determination part is configured to determine that the rotary machine is abnormal when the first index as the abnormality index is not less than the threshold.

16. The diagnosis apparatus for a rotary machine according to claim 13, comprising a divided waveform acquisition part configured to acquire a divided waveform with a specified number of pulses from the current waveform,
wherein the effective value acquisition part is configured to acquire the effective value of the current for each divided waveform.

17. The diagnosis apparatus for a rotary machine according to claim 16,
wherein the divided waveform acquisition part is configured to acquire a plurality of the divided waveforms by dividing the current waveform at a plurality of zero-crossing points of the current waveform where the current passes through zero and a sign of the current changes in the same direction.

18. The diagnosis apparatus for a rotary machine according to claim 17,
wherein the current waveform is represented as a curve connecting measurement values of the current acquired at a specified sampling period, and
wherein the divided waveform acquisition part is configured to identify the zero-crossing points by linear interpolation of two of the measurement values with different signs.

19. The diagnosis apparatus for a rotary machine according to claim 18, comprising a filter configured to reduce noise components from a signal indicating the current,
wherein the divided waveform acquisition part is configured to identify the zero-crossing points on the basis of the signal processed by the filter.

20. The diagnosis apparatus for a rotary machine according to claim 19, comprising a filter setting part configured to increase a time constant of the filter so that a difference between a maximum value and a minimum value of the number of sampling measurement values of the current included in each of the plurality of divided waveforms falls within an allowable range.

21. The diagnosis apparatus for a rotary machine according to claim 20,
wherein the filter setting part is configured to repeatedly increase the time constant by a predetermined amount until the difference falls within the allowable range.

22. A diagnosis method for a rotary machine, comprising:
a step of acquiring, from a current waveform of a current measured during rotation of a rotary machine including a motor or a generator, an effective value of the current;
a step of acquiring a first index indicating a dispersion of a distribution of the effective value;
a step of determining whether there is an abnormality in the rotary machine on the basis of comparison of an abnormality index including the first index with a threshold; and
a step of acquiring a second index indicating a divergence of an average value of the effective value from a theoretical value,
wherein the abnormality determination step includes determining whether there is an abnormality in the rotary machine on the basis of comparison of the abnormality index including the first index and the second index with the threshold.

23. A diagnosis program for a rotary machine for causing a compute to execute:
a process of acquiring, from a current waveform of a current measured during rotation of a rotary machine including a motor or a generator, an effective value of the current;
a process of acquiring a first index indicating a dispersion of a distribution of the effective value;
a process of determining whether there is an abnormality in the rotary machine on the basis of comparison of an abnormality index including the first index with a threshold; and
a process of acquiring a second index indicating a divergence of an average value of the effective value from a theoretical value,
wherein the abnormality determination process includes determining whether there is an abnormality in the rotary machine on the basis of comparison of the abnormality index including the first index and the second index with the threshold.
